(19) United States
(12) Patent Application Publication
(10) Pub. No.: US 2025/0201690 A1
(43) Pub. Date: Jun. 19, 2025

(54) SYSTEM AND METHODS FOR AN EMBEDDED BRIDGING PACKAGE ARCHITECTURE

(71) Applicant: Samsung Electronics Co., Ltd., Suwon-si (KR)

(72) Inventors: Jin YANG, San Jose, CA (US); Ramkumar SUBRAMANIAN, San Jose, CA (US); Sriram BALASUBRAMANIAN, Fremont, CA (US); Martin SCOTT, San Francisco, CA (US)

(21) Appl. No.: 18/882,717

(22) Filed: Sep. 11, 2024

Related U.S. Application Data
(60) Provisional application No. 63/612,351, filed on Dec. 19, 2023.

(51) Int. Cl. H01L 23/498; H01L 23/00; H01L 23/31; H01L 23/48; H01L 23/64; H01L 25/18

(52) U.S. Cl. CPC H01L 23/49827; H01L 23/3128; H01L 23/3157; H01L 23/481; H01L 23/49816; H01L 23/642; H01L 24/16; H01L 24/24; H01L 24/32; H01L 24/73; H01L 24/743; H01L 24/75; H01L 25/18; H01L 2224/16225; H01L 2224/24137; H01L 2224/24225; H01L 2224/32225; H01L 2224/73204; H01L 2224/743; H01L 2224/7595; H01L 2924/1205; H01L 2924/3011

(57) ABSTRACT

Disclosed herein are methods, systems and devices including a first layer with a first compute device, a first device stack, and a second device stack between the first device stack and the first compute device. A second layer may be mounted on top of the first layer. The second layer may include a first bridge electrically connecting the first compute device to the first device stack and a second bridge electrically connecting the first compute device to the second device stack.

### CROSS-REFERENCE TO RELATED APPLICATION

This application claims the priority benefit under 35 U.S.C. § 119 (e) of U.S. Provisional Application No. 63/612,351 filed on Dec. 19, 2023, the disclosure of which is incorporated herein by reference in its entirety.

### TECHNICAL FIELD

The subject matter disclosed herein relates to microelectronics packaging and integrated circuits (IC) packaging. More particularly, the subject matter disclosed herein relates to a package architecture including an embedded bridge.

### BACKGROUND

Semiconductor devices may connect to additional devices and circuitry on different substrates. Forming connections between substrates can provide increased computation. However, forming connections between substrates can cause complications. Packaging describes the general method for connecting and integrating multiple computational components together in an integrated unit, and may involve multiple different types of integrated circuits on multiple substrates which may combine into a single unit. Packaging may also describe the method for which multiple computational components within a single unit are protected by the use of various techniques to provide thermal, physical and electrical protection. Background concepts discussed herein are for informational purposes only and are not intended to limit the present disclosure. Nor should the background or field described herein be intended to limit the disclosure herein to a particular use or concept.

### SUMMARY

An example embodiment provides a device including a first layer with a first compute device, a first device stack, and a second device stack between the first device stack and the first compute device. The device may include a second layer on top of the first layer. The second layer including a first bridge and a second bridge, the first bridge electrically connecting the first compute device to the first device stack and the second bridge electrically connecting the first compute device to the second device stack. In some embodiments, the first layer includes a third device stack and a fourth device stack, the fourth device stack arranged between the third device stack and the first compute device. In some embodiments, the second layer may include a third bridge and a fourth bridge, the third bridge electrically connecting the first compute device to the third device stack and the fourth bridge electrically connecting the first compute device to the fourth device stack. In some embodiments, the first compute device is between the second device stack and the fourth device stack. In some embodiments, the first compute device is between the first bridge and the third bridge. In some embodiments, the first compute device, the third device stack, and the fourth device stack are mounted over the third bridge and the fourth bridge. In some embodiments, the first compute device, the first device stack, and the second device stack are mounted over the first bridge and the second bridge. In some embodiments, within the second layer is a first redistribution layer on a first side facing the first layer, and a second redistribution layer on a second side opposite the first side. In some embodiments, the first redistribution layer is between the first bridge and the first compute device. In some embodiments, the first device stack include at least one of a memory device and a processing device. In some embodiments, the second layer may include a capacitor to filter impedance.

An example embodiment provides a device with a first layer including a first compute device, a first device stack and a second device stack, the second device stack between the first device stack and the first compute device. The device may include a second layer with a first bridge electrically connecting the first compute device to the first device stack, and the first bridge electrically connecting the first compute device to the second device stack. The first layer may include a second compute device, a third device stack and a fourth device stack, the first device stack between the third device stack and the second compute device. The second layer may include a second bridge, the second bridge electrically connecting the second compute device to the third device stack, and the second bridge electrically connecting the second compute device to the fourth device stack. The second compute device, the third device stack and the fourth device stack may be mounted on top of the second bridge. The second bridge may have a first trace electrically connecting the second compute device and the third device stack and a second trace electrically connecting the second compute device and the fourth device stack. The first compute device, the first device stack, and the second device stack may be mounted on top of the first bridge, and the first bridge may include a first trace to electrically connect the first compute device and the first device stack, and a second trace may electrically connect the first compute device and the second device stack. The first device may include at least one of a memory die and a processing device. The first layer may include a base die arranged between the first compute device and the first bridge.

An example embodiment provides a method, the method including forming a bridging layer having a first bridge and a second bridge, forming a first redistribution layer on a first side of the bridging layer, the first redistribution layer communicatively connected to the first bridge and the second bridge. A compute device may be mounted on the bridging layer and on the first redistribution layer. A first device stack and a second device stack may be mounted on the bridging layer and on the first redistribution layer, with the second device stack between the first device stack and the compute device. A dielectric layer may be formed over the bridging layer. The first device stack may be coupled to the compute device via the first bridge, and the second device stack may be coupled to the compute device via the second bridge. The first device stack and the second device stack may have substantially the same devices. The first device stack and the second device stack may have different devices. Forming the bridging layer may include forming a second redistribution layer on a second side of the bridging layer opposite the first side of the bridging layer. Forming the dielectric layer over the bridging layer may include depositing dielectric material between the first device stack, the second device stack, and the compute device. Mounting the compute device on the bridging layer may include mounting a base die on the first redistribution layer, and mounting the compute device on the base die.

### BRIEF DESCRIPTION OF THE DRAWING

In the following section, the aspects of the subject matter disclosed herein will be described with reference to exemplary embodiments illustrated in the figures, in which:

FIG. 1 depicts a perspective view of an example embodiment of a packaging structure according to various embodiments of the subject matter disclosed herein;

FIG. 2 depicts a cross-section view of an example embodiment of a packaging structure according to various embodiments of the subject matter disclosed herein;

FIG. 3A depicts a plan view of an example embodiment of a packaging structure assembly according to various embodiments of the subject matter disclosed herein;

FIG. 3B depicts a plan view of an example embodiment of a packaging structure assembly according to various embodiments of the subject matter disclosed herein;

FIG. 4A depicts a cross-section view of an example embodiment of a packaging structure assembly at a first time according to various embodiments of the subject matter disclosed herein;

FIG. 4B depicts a cross-section view of an example embodiment of a packaging structure assembly at a second time according to various embodiments of the subject matter disclosed herein;

FIG. 4C depicts a cross-section view of an example embodiment of a packaging structure assembly at a third time according to various embodiments of the subject matter disclosed herein;

FIG. 4D depicts a cross-section view of an example embodiment of a packaging structure assembly at a fourth time according to various embodiments of the subject matter disclosed herein;

FIG. 4E depicts a cross-section view of an example embodiment of a packaging structure assembly at a fifth time according to various embodiments of the subject matter disclosed herein;

FIG. 4F depicts a cross-section view of an example embodiment of a packaging structure assembly at a sixth time according to various embodiments of the subject matter disclosed herein;

FIG. 4G depicts a cross-section view of an example embodiment of a packaging structure assembly at a seventh time according to various embodiments of the subject matter disclosed herein;

FIG. 5 depicts an example embodiment of a method of forming a package structure according to various embodiments of the subject matter disclosed herein;

FIG. 6 depicts a plan view of an example embodiment of a packaging structure assembly according to various embodiments of the subject matter disclosed herein and

FIG. 7 depicts a plan view of an example embodiment of a packaging structure assembly according to various embodiments of the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” etc.) may be occasionally interchangeably used with a corresponding non-hyphenated version (e.g., “two dimensional,” “predetermined, etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein substrates may refer to a variety of materials and structures, including wafers using silicon, wafers using silicon on an insulator (SOI) such as glass, wafers of other semiconductor materials such as germanium, as well as other semiconductor materials on an insulator. In some embodiments, a substrate may include an organic material. In some embodiments, the substrates may be referred to as wafers, dies, and chips alone or in combination. Bonding substrates may be thus known in some embodiments as die-to-die (D2D) bonding, wafer-to-wafer bonding (W2W) or die-to-wafer bonding (D2W). In some embodiments, the substrates may contain circuits such as integrated circuits including central processing units (CPUs), logic chips, memory such as static random-access memory (SRAM), dynamic random-access memory (DRAM), synchronous dynamic random-access memory (SDRAM), double data rate DRAM or DDR DRAM, application processors (AP), graphical processing units (GPUs), other forms of auxiliary processing units (xPU), Artificial intelligence (AI) chips, High bandwidth memory (HBM) interfaces, and other application-specific integrated circuits (ASIC). In some embodiments, a combination of circuits may be present on a substrate. In some embodiments, a substrate may include a packaged chip.

As used herein, high bandwidth memory or HBM, may refer to a chip structure including one or more HBM modules. In some embodiments, the HBM may be manufactured by an advance silicon node process.

As used herein packaging refers to a process of forming interconnections between substrates. In some embodiments, the interconnections may be between direct surfaces and involve W2W, D2D, and D2W bonding. In other embodiments, techniques including wire bonding and other forms of indirect bonding may be performed alone or in combination with W2W, D2D, and D2W bonding. In some embodiments, circuits may be bonded directly facing each other, while in other embodiments a flip-chip bonding may be used. In some embodiments, interconnections may be made between substrates on a front or circuit side of the substrate. In other embodiments, interconnections may be made on a rear or back side of the substrate opposite from the circuit structure. In some embodiments, an interconnection may include through-silicon vias (TSVs) or other forms of through-chip vias where one or more substrates may be connected using a via traveling through an interposer such as another substrate or chip. In some embodiments, an interconnection may be formed using connections on a surface of a substrate, such as a pad, and may use additional materials between the pads such as solder to form an interconnection.

As used herein, conductors may refer to a variety of conductive materials, including which materials may be used alone or in combination with other materials such as in the form of an alloy. In some embodiments the conductor is copper (Cu). In some embodiments, copper (Cu) may be in the form of Cu (II), Cu (III) or other forms of copper, alone or in combination with additional elements, including cobalt (Co) and Ruthenium (Ru). Such a listing of elements is not intended to be exhaustive, and in other embodiments, any known other type of conductive material may be used.

As used herein, a bridge refers to a substrate, die, or other material having one or more conductive pathways able to form connection between one or more semiconductor devices, as well as substrates, interposers, or other package structures. A bridge may include one or more traces, the traces forming a connection pathway along the bridge between one or more devices coupled to the bridge. An embedded bridge, as used herein, may refer to a bridge in a layer within a semiconductor package, and may be used interchangeably with bridge.

Disclosed herein are various embodiments of devices, systems and methods related to packaging architecture to modularly create a stack logic and memory building block architecture using hybrid bonding. As used herein, hybrid bonding may be defined as bonding both conductive portions to conductive portions, and dielectric portions to dielectric portions. A stack logic and memory building block architecture may include a base chip providing logic, routing, and power delivery to a stack of memory. As used herein, a device stack or stack of devices may refer to a combination of memory and supporting circuit architecture, for example, chiplets and dies containing individual memory elements, supporting processing units, I/O circuitry, and other forms of integrated chips.

In some embodiments, a backside power delivery network (BSPDN) may be formed on the backside of a substrate, with a signal network formed on the front side of the same substrate. In some embodiments, the BSPDN and signal network may be formed on separate substrates and transferred to the same substrate. The BSPDN and signal network may be separated by a transistor layer. The transistor layer may include a plurality of transistors. The transistors may provide different functions and take different forms, including a logic layer. The BSPDN and signal network may form a single monolithic structure on the same die in a semiconductor foundry process. A stacked device module may be separately be formed in a semiconductor foundry process, the same semiconductor foundry process, or may have multiple components formed in multiple semiconductor foundry processes and assembled in a packaging assembly process.

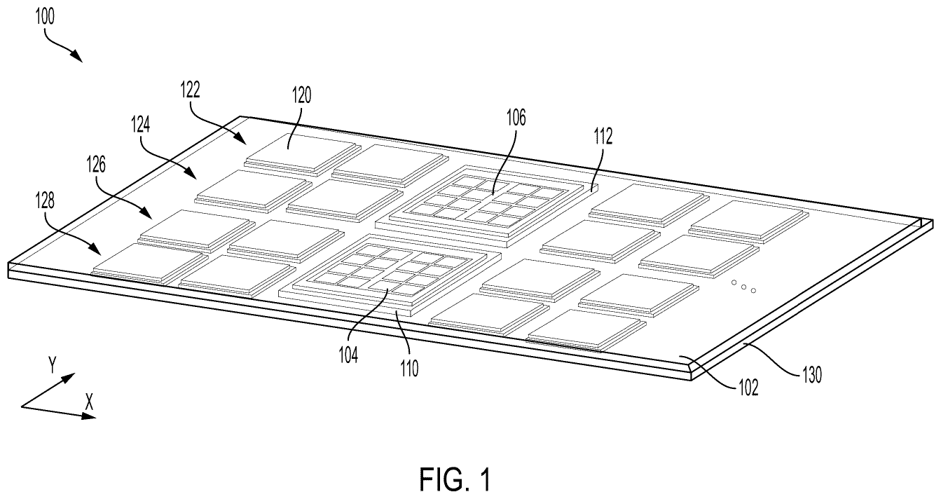

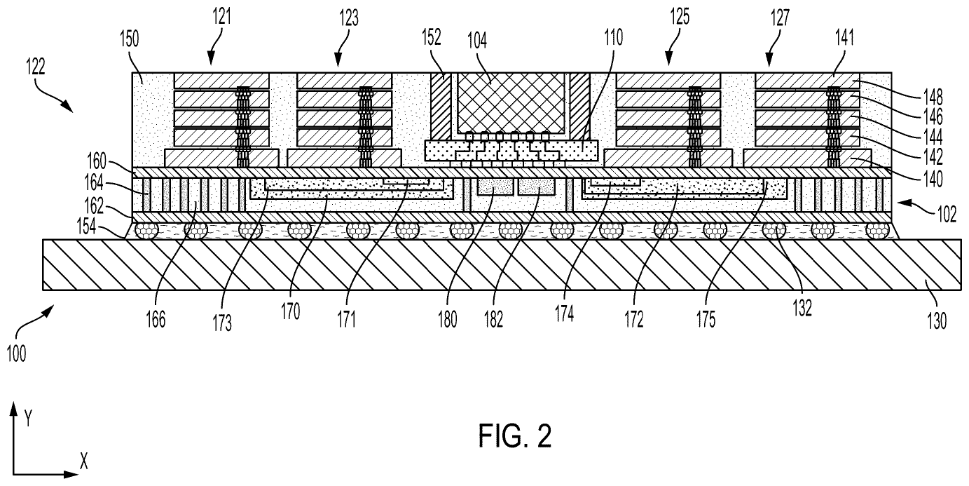

FIG. 1 depicts an exemplary embodiment of a device package architecture 100 in a cross-section view. FIG. 2 depicts the device package architecture 100 of FIG. 1 in a cross-sectional view. A plurality of device stacks 120 are mounted on a bridging layer 102. The bridging layer 102 connects the device stacks 120 to a first compute device 104 and a second compute device 106. The first compute device 104 may be on a first base die 110, and the second compute device 106 may be mounted on a second base die 112. In some embodiments, a single compute device may be used, while in other embodiments, additional compute devices may be added, for example 4, 6, 8, 16 or 32 compute devices may be added. In some embodiments, the first compute device 104 and the second compute device 106 may share the same base die, while in other embodiments, each compute device may have a separate base die. In some embodiments, the base die may be a silicon die, while in other embodiments a variety of semiconductor materials may be used. In some embodiments, the compute devices may include a die, a core, or chiplet, as well as any other suitable form of circuit. As used herein, a chiplet may refer to an integrated circuit having a well-defined functionality, such as a microprocessor, a memory device, or other computational function; with a chiplet enabling a modular design with multiple chiplets able to be combined with a larger package, sharing a substrate or interposer to form a larger device. A core may refer to a single-unit of a multicore device where multiple devices form a larger device, with each device able to function independently to enable multiple streams of operations. In some embodiments, a core may take the form of a chiplet, or a chiplet may take the form of a core. However, in other embodiments, a chiplet may take the form of any other suitable integrated circuit. In some embodiments, one or more dummy layers 152 may be on either side of each of the compute devices. In the example embodiment of FIG. 2, a pair of dummy layers 152 surround the first compute device 104. In some embodiments, the dummy layers 152 may be a dummy silicon layer, and may provide thermal, electrical, and structural support for the package architectures.

Additionally, an encapsulation layer 150 may surround the compute devices and the device stacks 120, the encapsulation layer 150 being a dielectric material, and in some embodiments, the encapsulation layer 150 may provide mechanical support, such as holding the devices in places, as well as may provide electrical isolation, and may provide a thermal path for heat from the devices to transfer via. In some embodiments, the encapsulation layer 150 may be an epoxy molding compound or resin. The encapsulation layer 150 may, in some embodiments, comprise one or more encapsulation layers, and may include individual encapsulation layers on the device stacks 120 to encapsulate the individual stacks, as well as encapsulation layers to encapsulate the first compute device 104 and the second compute device 106.

The device stacks 120 may be formed into a series of lanes, with a first device lane 122, a second device lane 124, a third device lane 126, and a fourth device lane 128 shown in FIG. 1. In some embodiments, additional device lanes may be added, to create 6, 8, 10, 16, 32 or more lanes of devices. In the example embodiment of FIG. 1, each device lane has 4 of the device stacks 120, with the first device lane 122 and the second device lane 124 each having two device stacks on each side of the second compute device 106. In FIG. 2, the device stacks 120 of the first device lane 122 is shown, including a first device stack 121, a second device stack 123, a third device stack 125, and a fourth device stack 127. In other embodiments, the number of the device stacks 120 in each lane may differ, and each lane may have 4, 6, 8, 12, 16 or more of the device stacks 120 per lane. In the example embodiment of FIG. 1, each compute device has a pair of device lanes aligned with each compute device, with the first compute device 104 having the first device lane 122 and the second device lane 124, and the second compute device 106 having the third device lane 126 and the fourth device lane 128.

The device stacks 120 may include multiple devices in the form of chips or dies. In the embodiment of FIG. 2, the fourth device stack 127 is shown having an example of 5 devices stacked on top of each other, including a first device 140, a second device 142, a third device 144, a fourth device 146, and a fifth device 148. In some embodiments, the devices may be various forms of memory including DRAM, SRAM, and other forms of memory. In some embodiments, the devices may include a core device, for example a processor or other form of microcontroller to act as a controller. In the example embodiment of FIG. 2, the fourth device stack 127 is shown having the first device 140 which can take the form of a compute die to act as the core for the fourth device stack 127. The second device 142 may take the form of a chiplet, such as a DRAM die or another core die, and be stacked upon the first device 140. The second device 142 may connect to the first device 140 via a stack interconnection 141. The stack interconnection 141 may provide an interconnection between each device within the fourth device stack 127. The third device 144 may be mounted on top of the second device 142, and may take the form of a chiplet, such as a DRAM die or another core die. The third device 144 may connect to the first device 140 or the second device 142 via the stack interconnection 141. A fourth device 146 may be mounted on the top of the third device 144, and may take the form of a chiplet, such as a DRAM die or another core die. The fourth device 146 may connect to the first device 140, the second device 142, and the third device 144 via the stack interconnection 141. The fifth device 148 may be mounted on the top of the fourth device 146, and may take the form of a chiplet, such as a DRAM die or another core die. The fifth device 148 may connect to the first device 140, the second device 142, the third device 144, and the fourth device 146 via the stack interconnection 141. Additionally, a bonding layer may be between each device, such as a dielectric layer or an adhesive layer such as a resin or epoxy, or any other suitable dielectric material.

The number of devices within each stack may vary, and the number of devices and type of devices provided may vary based on the relative amount of computing desired for each device. For example, a desired ratio between core dies and memory dies may be desired, for example 1 core per 4 memory dies may be desired in some embodiments. However, in other embodiments, the ratio may vary, for example, and in some embodiments may be less and include 1 core per 2 memory dies, while in other embodiments, the ratio may be greater and include 1 core per 5, 6, 10, or even 15 memory die.

The device stacks 120 may be mounted on the bridging layer 102 to attach to the compute dies. The bridging layer 102 may include a first redistribution layer (RDL) 160 forming the top layer for the bridging layer 102, and may include a second RDL 162 forming the bottom layer for the bridging layer 102. A set of conductive posts 164 may connect between the first RDL 160 and the second RDL 162. In some embodiments, the conductive posts 164 may comprise a set of copper posts, while in other embodiments, the material may vary. Between the first RDL 160 and the second RDL 162, a molding layer 166 may fill in the spaces between the conductive posts 164, and form a support structure for additional elements which may be inserted into the molding layer 166. In some embodiments, the molding layer 166 may include a dielectric material such as silicon nitride (Si3N4) or silicon dioxide (SiO2). In some embodiments, a dielectric material in the molding layer 166 and a metallic material in the first RDL 160 may form a hybrid bond with the device stacks 120. In some embodiments, the first RDL 160 may include through-vias providing contact with the molding layer 166.

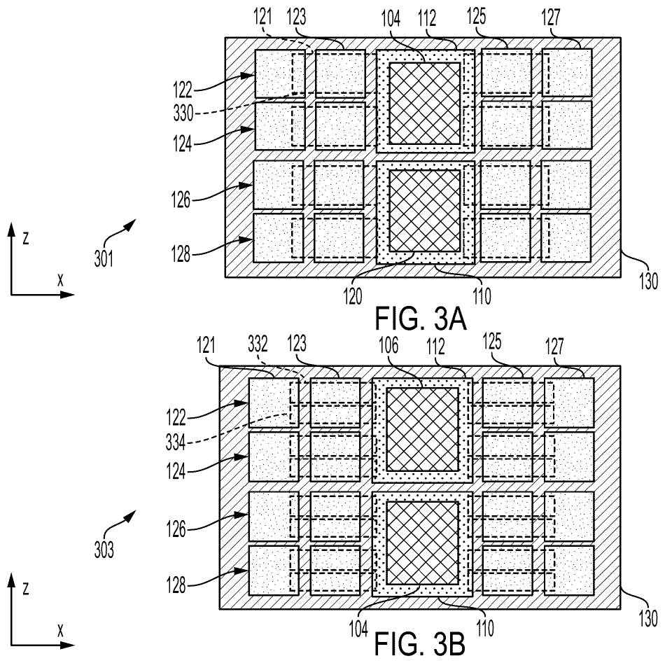

The bridging layer 102 may include one or more embedded bridges. FIG. 2 shows a first embedded bridge 170 and a second embedded bridge 172 embedded in the bridging layer 102. In some embodiments, the embedded bridges may comprise a semiconductor material such as silicon, although in other embodiments different semiconductors materials such as germanium may be used. In some embodiments, the embedded bridges may provide a routing structure for electrically coupling the device stacks 120 to the first compute device 104 and the second compute device 106. In the example embodiment of FIG. 2, the first embedded bridge 170 provides a first route 171 coupling the first compute device 104 to the first device stack 121, and also provides a second route 173 electrically coupling the first compute device 104 to the second device stack 123. Similarly, the second embedded bridge 172 provides a third route 174 to electrically couple the first compute device 104 to the third device stack 125, and also provides a fourth route 175 to electrically couple the first compute device 104 to the fourth device stack 127. The routes within the embedded bridges may be provided as traces, wires, buried lines, or any other known suitable method for providing a signal connection on or within a semiconductor device. Details of the embedded bridges will be further discussed below in regards to FIG.3A and FIG. 3B.

Additional devices may be incorporated into the bridging layer 102, for example, to provide signal routing and power delivery to the stack chips. In some embodiments, integrated stack capacitors (ISC) may be embedded within the bridging layer 102, and may provide capacitive power to the compute devices or the device stacks 120. In the example embodiment of FIG. 2, a first ISC 180 and a second ISC 182 may be embedded in bridging layer 102, below the first compute device 104. In some embodiments, an ISC may reduce the impedance of power in the device package architecture 100, and in some embodiments may be an impedance filter. In some embodiments, the impedance may reduce across a wide range of frequences, including ranges of 1-1000 MHz, while in other embodiments, the change in impedance may be greater or smaller.

The bridging layer 102 may be mounted on a supporting substrate 130. The supporting substrate 130 may in some embodiments be a silicon wafer, while in other embodiments, the supporting substrate 130 may include other semiconductor materials such as germanium, or may take the form of other substrates such as an organic substrate or even a SOI substrate such as glass. In some embodiments, the supporting substrate 130 may be a sacrificial substrate. Interconnections 132 may include pads, bumps, microbumps, pillars, balls, and other forms such as controlled-collapse chip connection (C4) bumps, alone or in combination. As used herein, a C4 bump refers to a form of solder bumps placed on pads on a top surface of a substrate prior to flipping the substrate to form a flip-chip. The supporting substrate 130 may in turn connect to other devices and dies, and in some embodiments, may take the form of an interposer. In some embodiments, interconnections 132 may further include a dielectric material, which may include a material such as an adhesive, resin, or elastomer which may form a connection between bridging layer 102 and the supporting substrate 130 in addition to a conductive connection. In some embodiments, the combination of a conductive connection and a dielectric connection may form a hybrid bond. In some embodiments, an underfill 154 may be placed between the supporting substrate 130 and the bridging layer 102. In some embodiments, the underfill 154 may be a material such as a dielectric, an epoxy, or a resin which may be inserted into the space between the supporting substrate and the bridging layer 102. In some embodiments, the underfill 154 may be inserted after the interconnections 132 are formed, and may provide additional bonding between the supporting substrate 130 and the bridging layer 102.

FIGS. 3A and 3B depict example embodiments showing a plan view of a first package layout 301 and a second package layout 303. The first package layout 301 and the second package layout 303 may be in the form of any of the disclosed device packages herein, including the device package architecture 100. The devices in FIG. 3A and FIG. 3B include a set of embedded bridges coupling the device stacks 120 to the compute dies.

FIG. 3A shows the first package layout 301 where a set of embedded bridges (indicated by the dashed rectangles of a first embedded bridge 330) electrically connects the device stacks 120 to the respective ones of the first compute device 104 and the second compute device 106. In FIG. 3A, each device lane has a pair of embedded bridges to electrically connect the device stacks 120 of each device lane to a compute die. For example, in the first device lane 122, the first embedded bridge 330 couples the first device stack 121 and the second device stack 123 to the first compute device 104, while an additional embedded bridge couples the third device stack 125 and the fourth device stack 127 to the first compute device 104. Likewise, embedded bridges connect the device stacks of the second device lane 124 to the first compute device 104. Additional embedded bridges may connect the third device lane 126 and the fourth device lane 128 to the second compute device 106. In some embodiments, where the number of device stacks in each device lane are greater than two per side, the embedded bridges may be lengthened to connect to the additional device stacks. In some embodiments, the embedded bridges may vary in width and may include multiple lanes in a single bridge, or multiple bridges for a single lane.

FIG. 3B provides a second package layout 303 where the first embedded bridge 330 of FIG. 3A is replaced by a pair of embedded bridges, including a first embedded bridge 332 and a second embedded bridge 334. The pair of embedded bridges may be referred to as a 2× embedded bridge. In the second package layout 303, the pair of embedded bridges may be specialized. In some embodiments, the pair of embedded bridges may be specialized for connecting to a particular die, for example, the first embedded bridge 332 may connect the first device stack 121 to the first compute device 104, and the second embedded bridge 334 may connect the second device stack 123 to the first compute device 104. In some embodiments, the pair of embedded dies may be each specialized for providing a specific form of coupling, for example, in some embodiments, the first embedded bridge 332 may provide for coupling input signals, while the second embedded bridge 334 may provide for coupling output signals. In some embodiments, for additional device stacks in each lane, an additional embedded bridge may be added to contact each additional device stack. In some embodiments, for additional device stacks in each lane, the pair of embedded bridges may be extended. Although discussed with respect to only the first device stack 121 and the second device stack 123, a pair of embedded bridges may be used for all of the device lanes, and to connect any of the device stacks 120 to the compute devices.

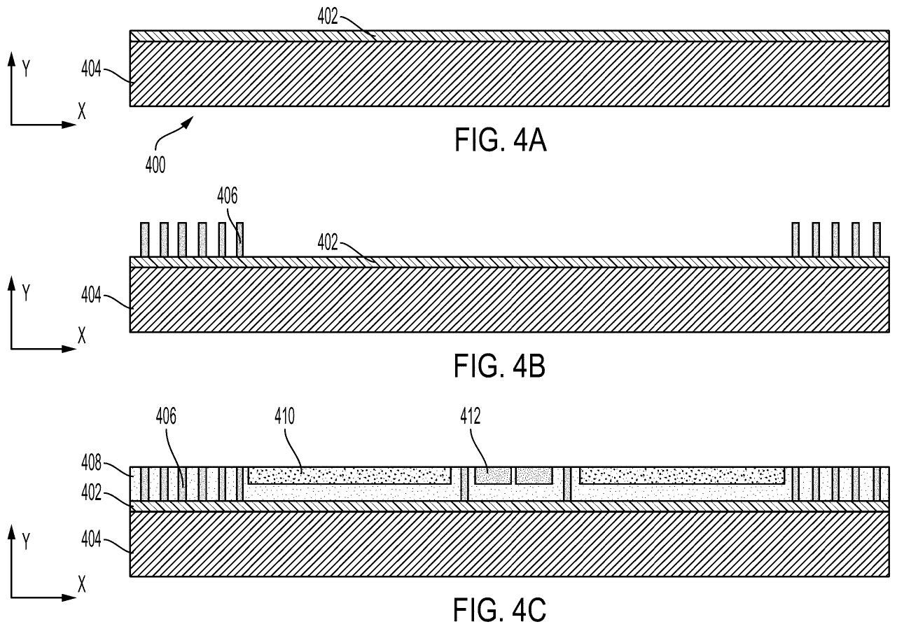

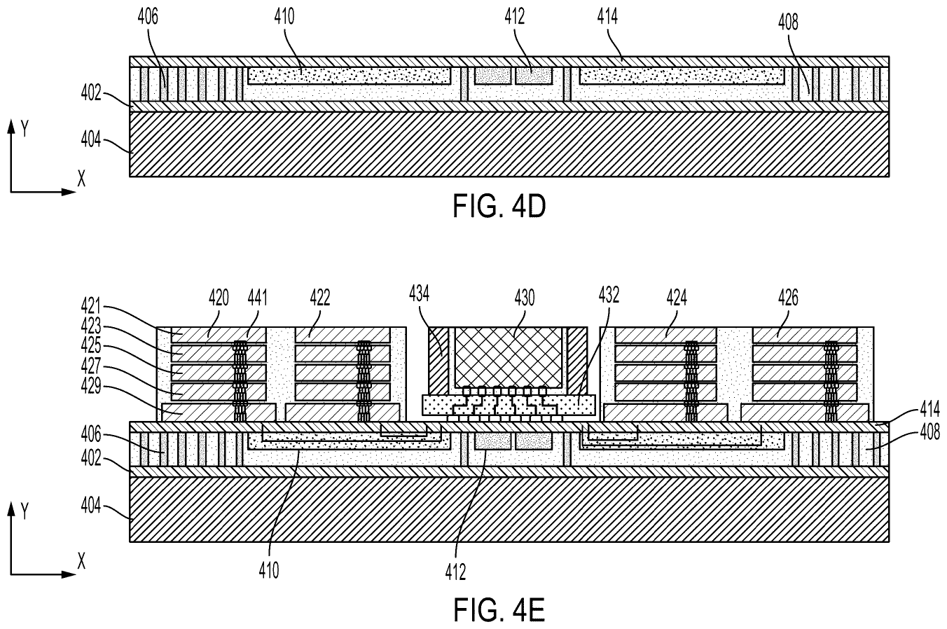

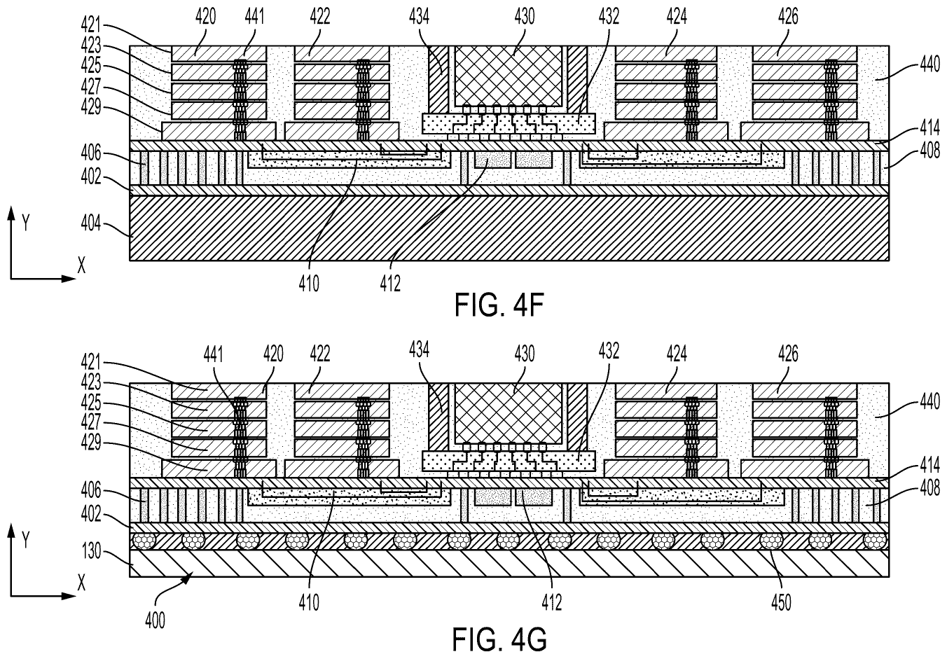

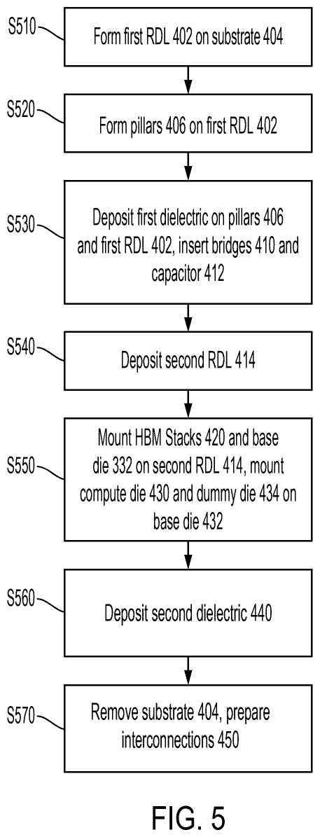

FIGS. 4A-4G depict an illustrative embodiment of a process of forming a device package architecture such as device package architecture 100, or any other device package architectures shown herein. FIG. 5 depicts an example embodiment of a process 500 for forming a device package assembly corresponding to the illustrative embodiment of FIGS. 4A-4G. For purposes of facilitating discussion, the device package architecture produced according to the process illustrated in FIGS. 4A-4G is generically described as device package architecture 400.

FIG. 4A depicts at S510 in FIG. 5 where a first RDL 402 is formed on a first substrate 404. The first substrate 404 may be a glass carrier substrate. In some embodiments, the first substrate 404 may include a release layer deposited on the first substrate 404 prior to the formation of the first RDL 402. In some embodiments, the first RDL 402 may be formed using complementary metal-oxide-semiconductor (CMOS) processes, such as depositing, lithography, etching, passivation directly on the first substrate 404. In some embodiments, the first RDL 402 may be formed on a separate substrate and transferred to the first substrate 404.

FIG. 4B depicts at S520 in FIG. 5 where conductive pillars 406 are formed on the first RDL 402. The conductive pillars 406 may comprise a conductive material, including metals such as copper, as well as other known conductive materials, such as doped carbon. The conductive pillars 406 are bonded to the first RDL 402 and may form an interconnection layer for a second RDL 414 added later. In some embodiments, the conductive pillars 406 may be bonded using metal diffusion bonding between a metallic material forming the conductive pillars 406 and corresponding metal materials within the first RDL 402.

FIG. 4C depicts at S530 in FIG. 5 where a first molding layer 408 is deposited over the conductive pillars 406 and the first RDL 402. The first molding layer 408 may be a dielectric material, and the first molding layer 408 may be deposited to provide electrical separation between the first RDL 402 and the second RDL 414 added in at S540. The first molding layer 408 may also provide a dielectric surface for providing a hybrid bonding structure with the second RDL 414 with device stacks. The first molding layer 408 may also provide a surface for embedding embedded bridges 410 and ISCs 412 within. After embedding the embedded bridges 410 and the ISC 412, the surface of the embedded bridges 410, the ISC 412, the first molding layer 408 and the conductive pillars 406 may be subject to a process to smooth and or planarize the surface, the process including one or more grinding, polishing, and smoothing processes, including chemical mechanical polishing (CMP).

FIG. 4D depicts at S540 in FIG. 5 where the second RDL 414 is formed on the surface of the conductive pillars 406, the first molding layer 408, the embedded bridges 410 and the ISC 412. The second RDL 414 includes a series of pads, bumps, vias, through-vias, traces, and other forms of connection for redistributing signals from the embedded layers to an appropriate location on the top of second RDL 414. In some embodiments, a portion of the first molding layer 408 may be exposed to provide a suitable dielectric surface for forming hybrid bonds.

FIG. 4E depicts at S550 in FIG. 5 where the device stacks 120 and the compute devices are mounted to the structure comprised of the first RDL 402, the second RDL 414, and the embedded layers between them. A compute device 430 is mounted to the second RDL 414 using a base die 432. The base die 432 may provide additional interconnections and redistribution layers for the compute device 430. Additionally, dummy layers 434 may be provided to provide additional support. The base die 432, the compute device 430, and the dummy layers 434 may, in some embodiments, be assembled directly on the second RDL 414, while in other embodiments, part or all of the base die 432, the compute device 430, and the dummy layers 434 may be assembled prior to mounting on the second RDL 414. An encapsulating material such as a resin or epoxy may be deposited between the base die 432, the compute device 430, and the dummy layers 434. In some embodiments, the encapsulating material may be deposited prior to mounting the base die 432, the compute device 430, and the dummy layers 434 on the second RDL 414, while in other embodiments the encapsulating material may be deposited after mounting the base die 432, the compute device 430, and the dummy layers 434 on the second RDL 414. Additionally, in some embodiments, the device stacks may be assembled prior to mounting on the second RDL 414, or may be assembled in place on the second RDL 414. As shown in the example of FIG. 4E, a first device stack 420, a second device stack 422, a third device stack 424, and fourth device stack 426 are mounted on the second RDL 414. Although described below is the layout of the first device stack 420, the description may be applied as well to any of the other device stacks described herein.

The first device stack 420 is shown with a first device 421 forming the top layer of the first device stack 420, a second device 423 below the first device 421, a third device 425 below the second device 423, a fourth device 427 below the third device 425, and a fifth device 429 below the fourth device 427 and above the second RDL 414. The fifth device 429 may be mounted directly on the second RDL 414 and further connect to one of the embedded bridges 410. The first device 421, the second device 423, the third device 425, the fourth device 427 and the fifth device 429 may each include a memory die, a chiplet, or a core controller. In some embodiments the fifth device 429 may include a core controller, and the first device 421, the second device 423, the third device 425, and the fourth device 427 may include a memory die or chiplet. In some embodiments, the first device 421, the second device 423, the third device 425, the fourth device 427 and the fifth device 429 may be electrically connected to an embedded bridge 410 via a set of interconnections 441. In some embodiments, an encapsulating material such as a resin or epoxy may be deposited on the device stacks to hold the device stacks together. In some embodiments, the encapsulating material may be deposited on the device stacks prior to mounting the device stacks on the second RDL 414.

FIG. 4F shows at S560 in FIG. 5 where a second molding layer 440 is deposited over the devices mounted on the second RDL 414. In some embodiments, the second molding layer 440 may be a dielectric material, and may provide a diffusion bonding surface between dielectric materials within the mounted devices and the first molding layer 408. In some embodiments, an additional planarization step may take place after depositing the second molding layer 440 to form an even surface. In some embodiments, the second molding layer 440 may be an adhesive layer such as a resin or an epoxy. In some embodiments, the second molding layer 440 may provide a supporting structure for the mounted devices, providing one or more of a thermal path for the transfer of heat form the mounted devices, structural support for keeping the mounted devices in place, and electrical isolation between the mounted devices.

FIG. 4G shows at S570 in FIG. 5 where the first substrate 404 is released from the first RDL 402. The first substrate 404 may be released, for example, by using one or more of layer release, chemical release, thermal release, or photo release techniques to release an adhesive layer coupling the first substrate 404 to the first RDL 402. For example, in some embodiments a chemical release technique may use a solvent to dissolve the adhesive directly, while a thermal release technique may apply heat to the carrier wafer to melt the adhesive, and a photo release technique may use lasers to directly apply energy to the adhesive layer to reduce the adhesive strength.

Additionally, at S570, interconnections 450 may be prepared for mounting the device package architecture 400 on to a supporting substrate or interposer such as supporting substrate 130. The interconnections 450 may include pads, bumps, microbumps, pillars, balls, and other forms such as C4 bumps, alone or in combination. After mounting the device package architecture 400 on supporting substrate 130, an underfill layer may be inserted between the device package architecture 400 and supporting substrate 130.

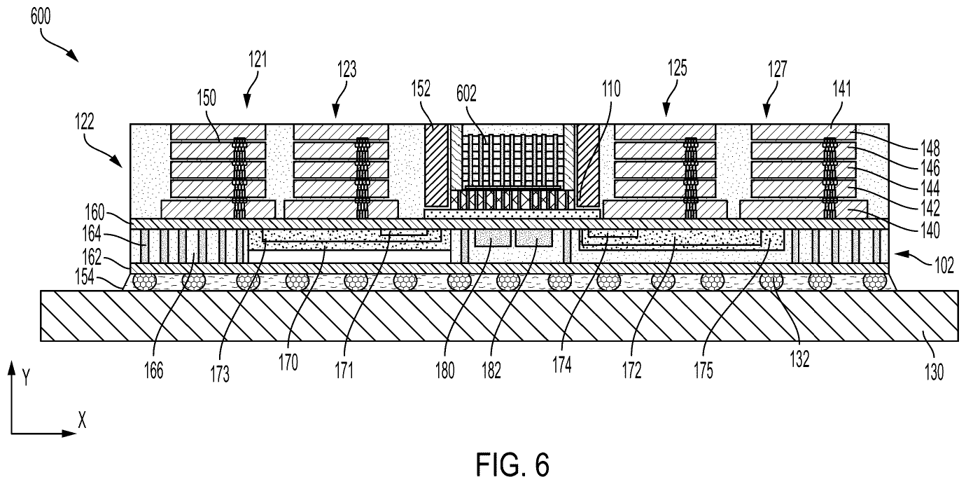

FIG. 6 depicts an exemplary embodiment of a device package architecture 600. The device package architecture 600 differs from the device package architecture 100 of FIGS. 1 and 2 by including a HBM device 602 in place of the first compute device 104. The HBM device 602 may include multiple memory die and multiple core controller devices. In some embodiments, the HBM device 602 may be mounted on top of a compute device similar to the first compute device 104. In some embodiments, mounting the HBM device 602 on top of a compute device may provide a direct connection, and may reduce the power usage and reduce the transfer latency.

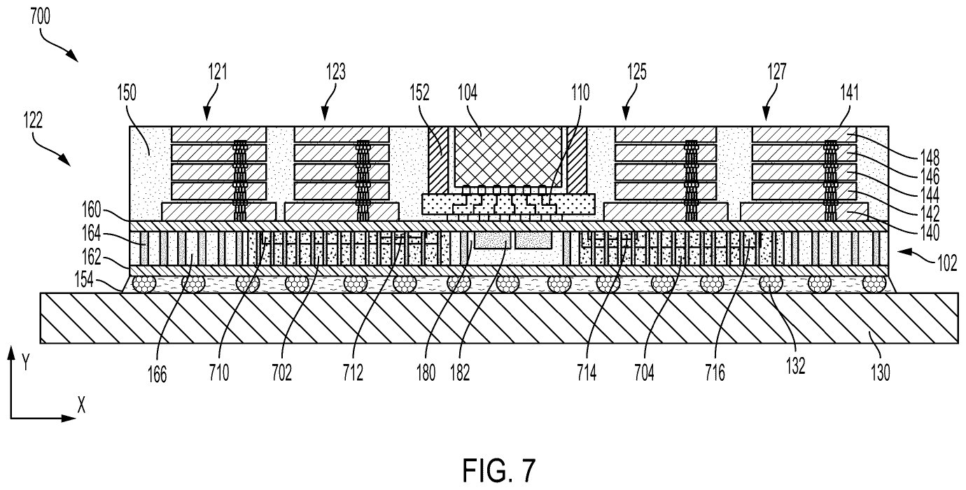

FIG. 7 depicts an exemplary embodiment of a device package architecture 700. The device package architecture 700 differs from the device package architecture 100 of FIGS. 1 and 2 by including thick embedded bridges, the thick embedded bridges having a thickness equal to the distance between the first RDL 160 and the second RDL 162. FIG. 7 shows a first thick bridge layer 702 providing support and connections between the first compute device 104 and the first device stack 121 with a first routing layer 710, and the first compute device 104 and the second device stack 123 with a second routing layer 712. A second thick bridge layer 704 similarly provides support and connections between the first compute device 104 and the third device stack 125 with a third routing layer 714, and the first compute device 104 and the fourth device stack 127 with a fourth routing layer 716.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A device comprising:
a first layer including a first compute device, a first device stack, and a second device stack between the first device stack and the first compute device; and
a second layer, on top of the first layer, including a first bridge and a second bridge, wherein the first bridge electrically connects the first compute device to the first device stack and the second bridge electrically connects the first compute device to the second device stack.

2. The device of claim 1, wherein the first layer includes a third device stack and a fourth device stack, wherein the fourth device stack is arranged between the third device stack and the first compute device; and
wherein the second layer further includes a third bridge and a fourth bridge, wherein the third bridge electrically connect the first compute device to the third device stack and the fourth bridge electrically connect the first compute device to the fourth device stack.

3. The device of claim 2, wherein the first compute device is arranged between the second device stack and the fourth device stack, and wherein the first compute device is arranged between the first bridge and the third bridge.

4. The device of claim 2, wherein the first compute device, the third device stack, and the fourth device stack are mounted over at least one member selected from a group including the third bridge and the fourth bridge.

5. The device of claim 1, wherein the first compute device, the first device stack, and the second device stack are mounted over at least one member selected from a group including the first bridge and the second bridge.

6. The device of claim 1, wherein the second layer includes a first redistribution layer on a first side facing the first layer, and wherein the second layer includes a second redistribution layer on a second side opposite the first side.

7. The device of claim 6, wherein the first redistribution layer is arranged between the first bridge and the first compute device.

8. The device of claim 1, wherein the first device stack includes at least one of a memory device and a processing device.

9. The device of claim 1, wherein the second layer includes at least one capacitor to filter impedance.

10. A device comprising:
a first layer including a first compute device, a first device stack, and a second device stack, wherein the second device stack is arranged between the first device stack and the first compute device; and
a second layer including a first bridge, the first bridge to electrically connect the first compute device to the first device stack, and the first bridge to electrically connect the first compute device to the second device stack.

11. The device of claim 10, wherein:
the first layer includes a second compute device, a third device stack, and a fourth device stack;
the fourth device stack is arranged between the third device stack and the second compute device;
the second layer includes a second bridge;
the second bridge to electrically connect the second compute device to the third device stack; and
the second bridge to electrically connect the second compute device to the fourth device stack.

12. The device of claim 11, wherein:
the second compute device, the third device stack and the fourth device stack are mounted on top of the second bridge; and
the second bridge including a first trace to connect the second compute device and the third device stack and a second trace to connect the second compute device and the fourth device stack.

13. The device of claim 10, wherein:
the first compute device, the first device stack and the second device stack are mounted on top of the first bridge; and
the first bridge including a first trace to connect the first compute device and the first device stack and a second trace to connect the first compute device and the second device stack.

14. The device of claim 10, wherein the first device stack includes at least one of a memory die and a processing device.

15. The device of claim 10, wherein the first layer includes a base die, and wherein the base die is arranged between the first compute device and the first bridge.

16. A method comprising:
forming a bridging layer including a first bridge and a second bridge, and forming a first redistribution layer on a first side of bridging layer, the first redistribution layer communicatively coupled to the first bridge and the second bridge;
mounting a compute device on the bridging layer and on the first redistribution layer;
mounting a first device stack and a second device stack on the bridging layer and on the first redistribution layer, the second device stack is arranged between the first device stack and the compute device;
depositing a dielectric layer over the bridging layer;
coupling the first device stack to the compute device via the first bridge; and coupling the second device stack to the compute device via the second bridge.

17. The method of claim 16, wherein the first device stack and the second device stack have substantially the same devices.

18. The method of claim 16, wherein mounting the compute device on the bridging layer includes mounting a base die on the first redistribution layer, and mounting the compute device on the base die.

19. The method of claim 16, wherein forming the bridging layer further comprises forming a second redistribution layer on a second side of the bridging layer, the second side of the bridging layer opposite the first side of the bridging layer.

20. The method of claim 16, wherein depositing the dielectric layer over the bridging layer includes depositing dielectric material between the first device stack, the second device stack and the compute device.
